(19) United States
(12) Patent Application Publication
(10) Pub. No.: US 2012/0126069 A1
(43) Pub. Date: May 24, 2012

(54) Bracket With Improved Cable Management

(76) Inventors: Daniel Kucer, Montreal West (CA); Gene Petit, Port Jervis, NY (US); Robert C. Baxter, Warwick, RI (US)

(21) Appl. No.: 13/278,031

(22) Filed: Oct. 20, 2011

Related U.S. Application Data
(60) Provisional application No. 61/405,027, filed on Oct. 20, 2010.

(51) Int. Cl. H05K 7/00

(52) U.S. Cl. 248/67.5

(57) ABSTRACT

A system according to an embodiment of the present invention comprises a base for attachment to, for example, the right side of a rack. The system further comprises at least one swing arm hingedly attached to the base. A cable support may be attached to the swing arm. The swing arm has a free end which is releasably attached to a latch plate. The latch plate is attached to the rack opposite the side of the base. In this way, the swing arm spans a part of the width of the rack from base to latch plate. The latch plate may move to enable access by a person to a fan tray of a network device installed in the rack.

### CROSS-REFERENCE TO RELATED APPLICATIONS

This application claims priority to U.S. provisional patent application No. 61/405,027, filed Oct. 20, 2010, the disclosure of which is incorporated herein by reference.

### BACKGROUND OF THE INVENTION

The invention relates generally to computer equipment and, namely, network devices such as, for example, local-area network (LAN) components, switches, routers, and equipment relating thereto. More specifically, the present invention relates to the management of cables, such as, for example, Ethernet (e.g., CAT-5, 5e, 6) or fiber optic cable, that are connected to such switches.

It is well known in the art that LANs commonly include one or more routers to control the traffic on a network. In smaller networks, a router commonly includes a built-in switch as well to enable more than one workstation computer to interconnect to the router using the above Ethernet cable. For ease of discussion, Ethernet will be referred to herein but any type of cable is pertinent to the present invention and the present invention, as described below, is intended to cover any type of cable.

However, larger networks may include multiple routers and external switches connected thereto so that many workstations can be interconnected to the network via Ethernet cable, or some other type of cable. This requires these multiple components to be organized in some fashion. As the network becomes larger, this becomes more and more important.

It is well known in the art to provide a rack mountable solution for organizing a number of switches and routers used in a LAN. Rack systems are well known in the art whereby the components of the routers and switches are provided in a standardized dimension, 19 or 23 inch wide and multiples of 1.75 inches high (one rack unit or RU or U) so they may be easily mounted bolted to holes along the vertical rails of a given rack. Such rack systems are so well known that further detail need not be provided for these systems.

The foregoing rack systems tend to get very hot thereby necessitating some type of additional cooling. To address this issue, a vertical fan tray is often mounted adjacent to the edge of the horizontally stacked and mounted switches and/or routers for such cooling.

There are a number of problems typically associated with prior art well known rack systems. While they are suitable for mounting components in an organized way, they do not manage the routing of cables to permit easy access to different components of the LAN equipment when the switches and other components are populated with Ethernet cable. FIG. 2 shows an example of a common prior art rack system and network device populated with Ethernet cable to Internet switches and other components together. As can be seen the vertically oriented fan tray is completely obstructed by the yellow Ethernet cable. Also, the Ethernet cables are very disorganized and further block access to a given switch or other rack-mounted component. This is a problem because this makes is also very difficult to remove a given switch for repair or replacement.

There have been attempts in the prior art to provide a solution to better organize the Ethernet cable. For example, clips, loops and zip ties have been attempted in the prior art but fail to fully address the problem of access to the fan tray and the individual rack-mounted components.

### SUMMARY OF THE INVENTION

A system according to an embodiment of the present invention comprises a base for attachment to, for example, the right side of a rack. The system further comprises at least one swing arm hingedly attached to the base. A cable support may be attached to the swing arm. The swing arm has a free end which is releasably attached to a latch plate. The latch plate is attached to the rack opposite the side of the base. In this way, the swing arm spans a part of the width of the rack from base to latch plate. The latch plate may move to enable access by a person to a fan tray of a network device installed in the rack.

### Description of the Drawings

For a fuller understanding of the nature and objects of the invention, reference should be made to the following detailed description taken in conjunction with the accompanying drawings, in which:

FIG. 1A shows a perspective view of a system according to an embodiment of the present invention, a portion of a rack, and the front panel of a network device.

FIG. 1B shows an elevation of the system and other components of FIG. 1A;

FIG. 1C shows a left side view of the system and other components of FIG. 1A;

FIG. 1D shows a right side view of the system and other components of FIG. 1A;

FIG. 1E shows a top view of the system and other components of FIG. 1;

FIG. 2 shows a prior art rack, network devices, and cables;

FIG. 3 shows a system of another embodiment of the present invention, network devices, and cables attached to the system;

FIG. 4A shows a perspective view of a portion of a rack employing a system of the present invention;

FIG. 4B is a perspective close up view of a portion of the latch plate of FIG. 4A;

FIG. 4C is another perspective close up view of a portion of the swing arm and latch plate of FIG. 4A;

FIG. 5A shows the system of FIG. 4A with the front panel of a fan tray removed;

FIG. 5B shows a perspective close up view of a portion of the latch plate of FIG. 5A;

FIG. 6 shows an example of a prior art network device with a fan tray and installed components;

FIG. 7 shows the swing arm of FIG. 4A in an operational (released) state;

FIG. 8A shows the system of FIG. 4A with a single swing arm in an operational (released) state;

FIG. 8B shows the system of FIG. 4A with all swing arms in an operational (released) state:

FIG. 9A shows the system of FIG. 4A with one swing arm in an operational (released) state allowing access to a component; and

FIG. 9B shows the system of FIG. 4A with all swing arms in an operational (released) state allowing access to a component.

### DETAILED DESCRIPTION OF THE INVENTION

The present invention preserves the advantages of prior art computer LAN rack-mount systems and methods. In addition, it provides new advantages not found in currently available systems and overcomes many disadvantages of such currently available systems.

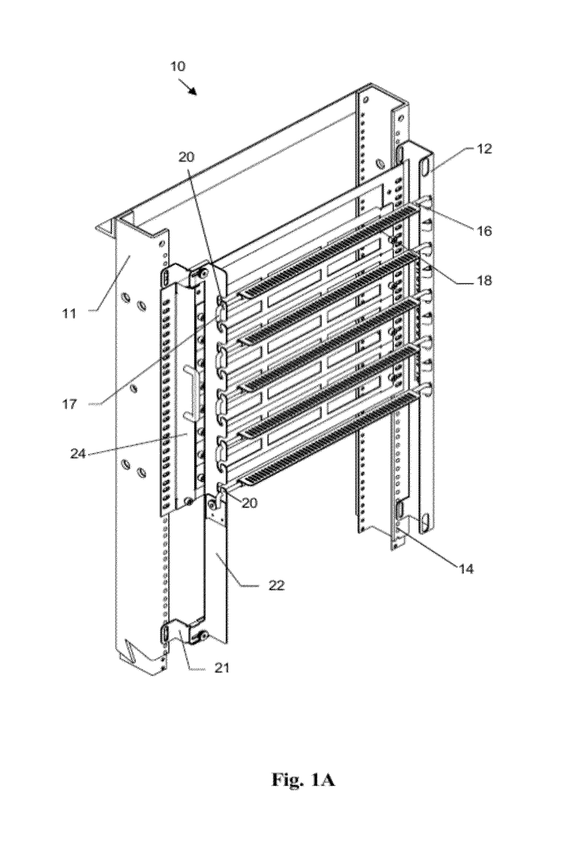

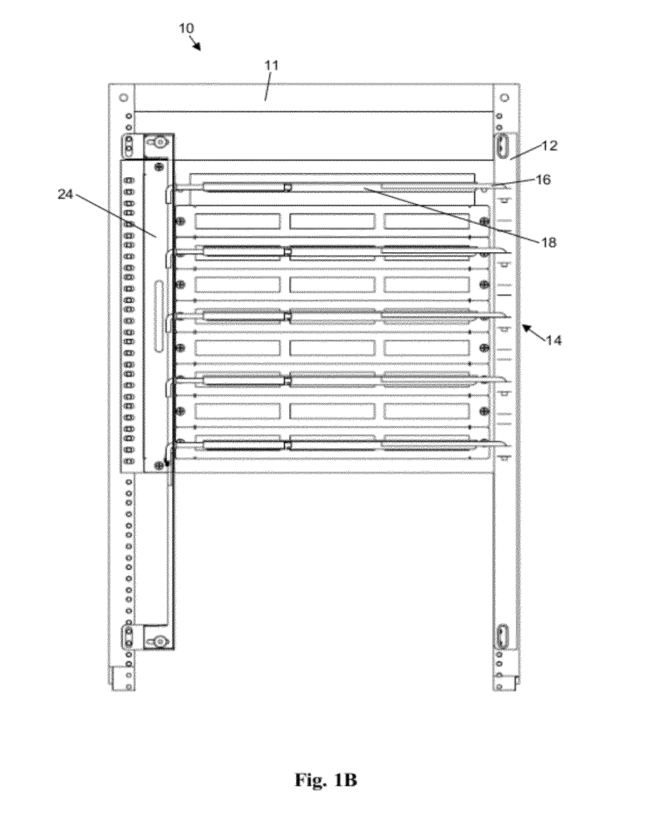

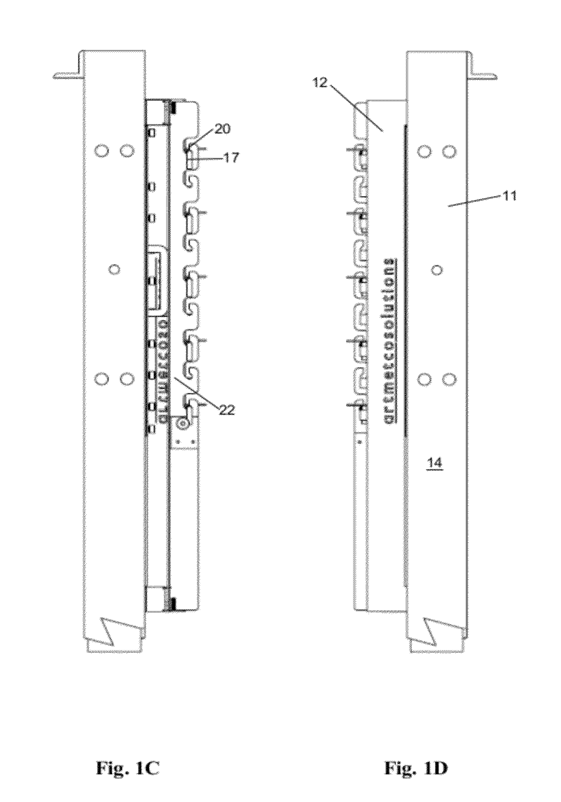

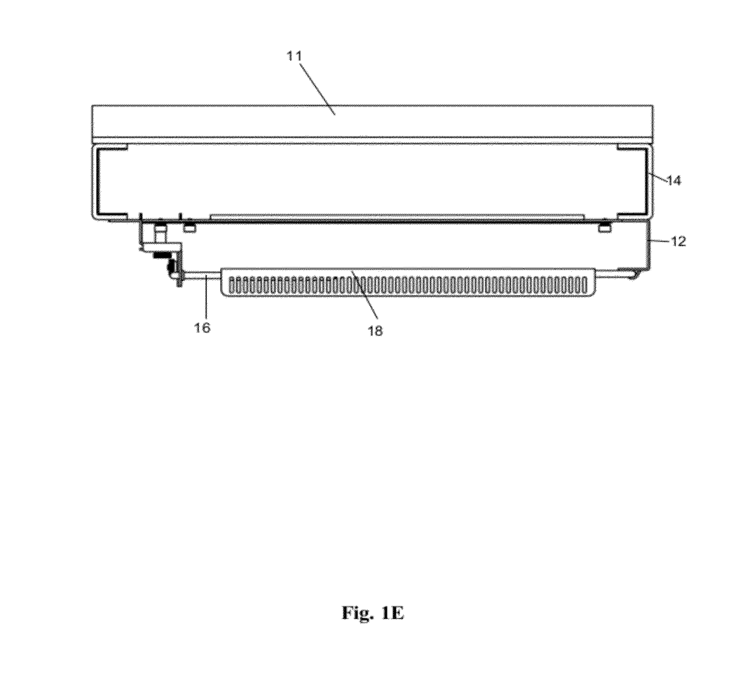

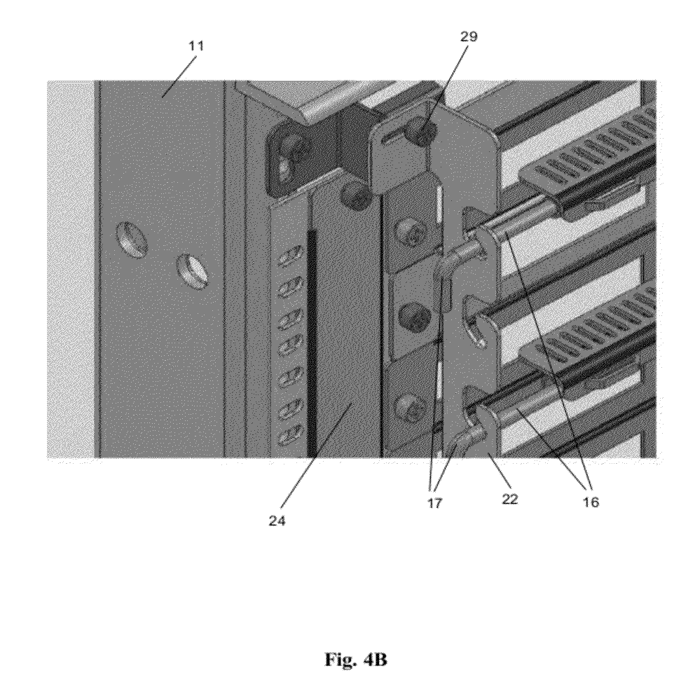

Turning first to FIGS. 1A-1E, a perspective view of a system 10 according to an embodiment of the present invention is shown installed on standard rack 11. A base 12 is attached to the right side 14 of the rack 11. Depending on the configuration of the network device used, the base 12 may alternatively be attached to the left side of the rack 11. (In this case, reference to direction/orientation below should be appropriately swapped). One or more swing arms 16 are pivotally attached thereto, such as on the right side 14, as shown. Affixed to the top of the swing arm 16 is a cable support 18, such as, for example, a grate or plate. A free end 17 of each swing arm 16 releasably interconnects to a hook-like interconnection 20 on a latch plate 22. The latch plate 22 may be attached to the rack 11 by a stand off bracket 21. The entire latch plate 22 may slide laterally to permit access to a fan tray 24 for its removal. The free ends 17 of the swing arms 16 may be individually releasable from their respective hooks 20 on the latch plate 22 so they may be swung outwards, with their Ethernet cables (26 in FIG. 3) conveniently rested thereon to permit access to a component 28, such as, for example, a switch, into which the cables 26 are plugged. FIG. 1B shows an elevational view of the system 10 of FIG. 1A, while FIGS. 1C and 1D shows left and right side views, respectively, of the system 10 of FIG. 1A, and FIG. 1D shows a top view of the system 10 of FIG. 1A.

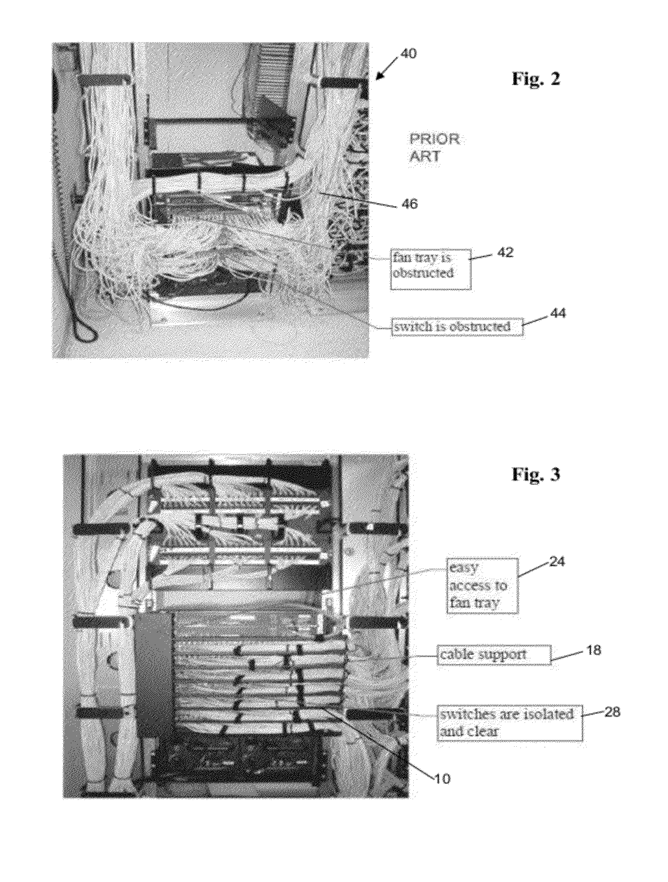

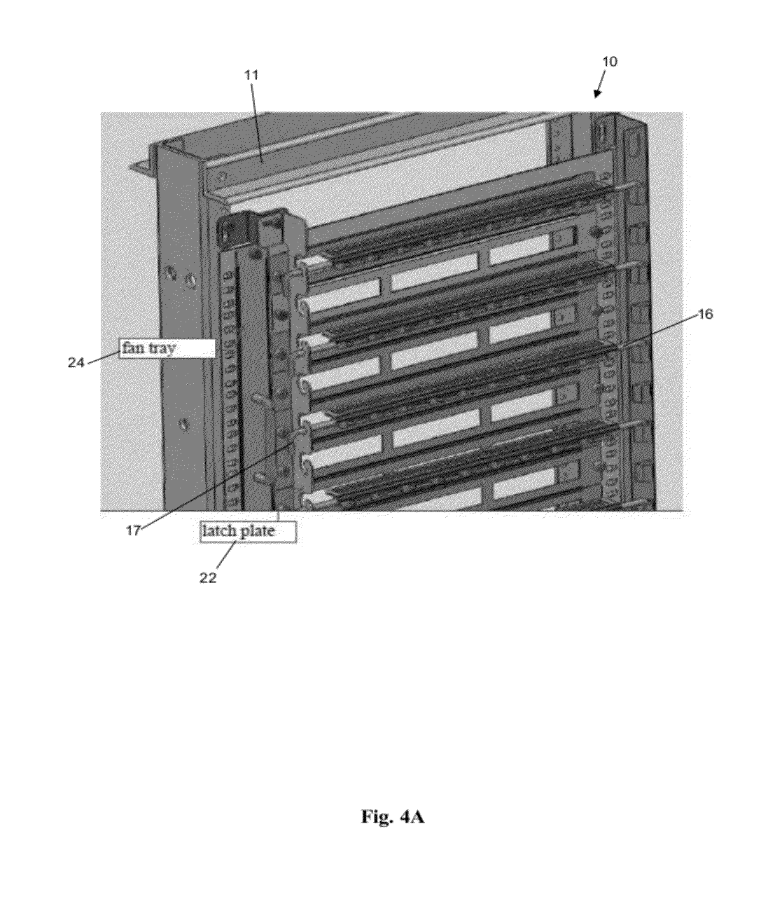

FIG. 2 illustrates the problem of the prior art rack system 40. FIG. 3 illustrates the solution provided by the present invention. FIG. 2 shows the fan tray 42 and the components 44 obstructed by the installed Ethernet cable 46. In contrast, FIG. 3 shows a rack system that is employing the system 10 of the present invention. As can be seen in FIG. 3, the cables 26 for a given component 28 (e.g. a switch) are shown resting on their corresponding cable support 18 that can be easily swung out after disconnection of the cables for replacement or repair of the component 28.

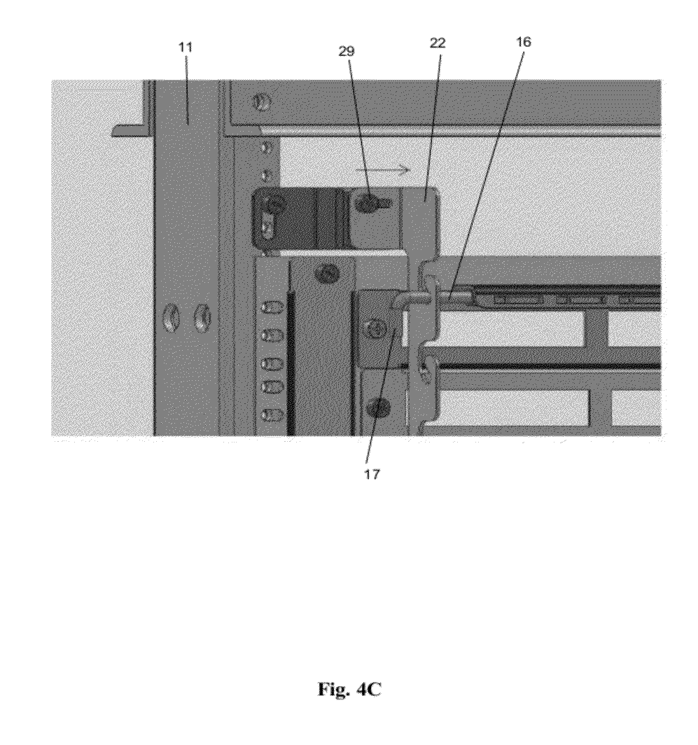

Turning now to FIGS. 4A-9B, the steps of operation of a rack 11 having a system 10 of the present invention is shown in detail. The Ethernet cables are removed for illustration purposes. FIG. 4A shows a rack 11 equipped with a system 10 of the present invention. The latch plate 22 is moved in a leftmost position in preparation for use. A close up of this is shown in FIG. 4B. In this location, the free ends 17 of the swing arms 16 block access to the fan tray 24. FIG. 4C shows a close-up of the interconnection of a free end 17 of the swing arm 16 and how the latch plate 22 slides to the right (in the direction of the arrow) after the nut 29 is loosened. The swing arm 16 may be telescoping or sliding so when the latch plate 22 slides to the right, the swing arm 16 shortens accordingly or slides laterally.

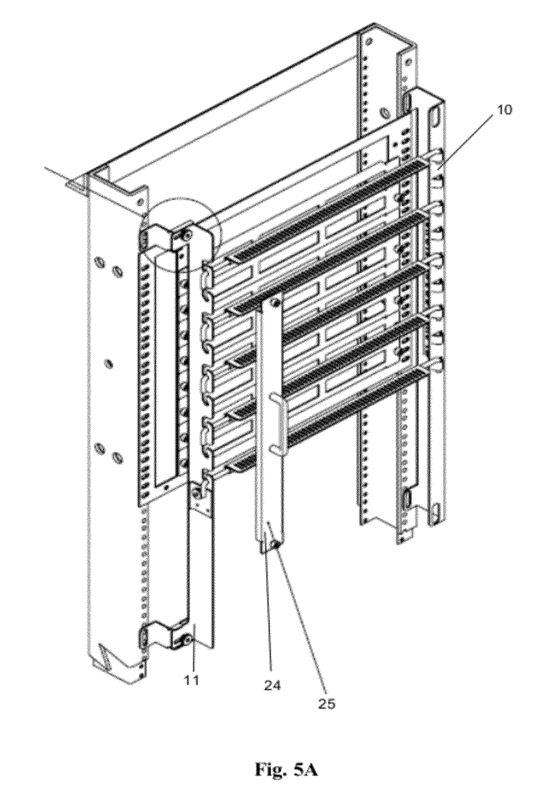

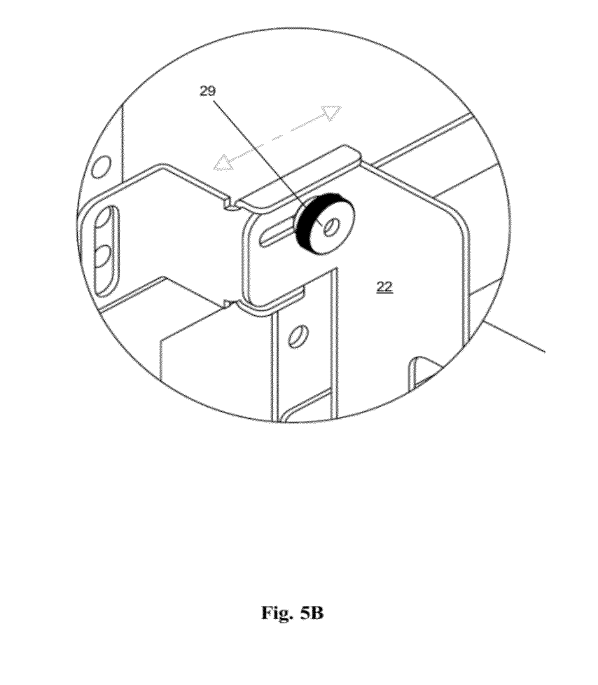

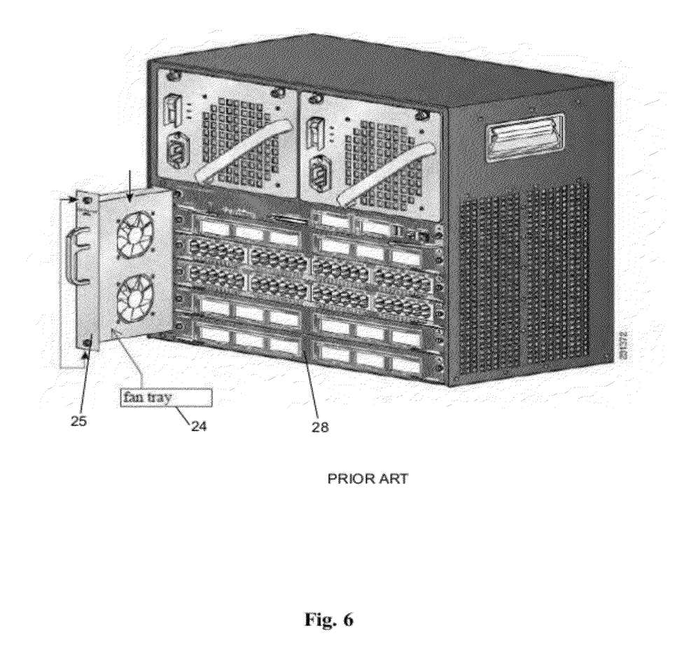

In FIG. 5A, it can be seen that there is free access to the fan tray 24, of which the front plate 25 thereof is shown. FIG. 5B shows a close up of how the latch plate 22 may move in the direction of the arrow after the nut 29 is loosened. FIG. 6 shows a full illustration of a fan tray 24 and how it slides into a chassis of a network device. The importance of access to the fan tray 24 is evident by this vertical sliding and location next to the horizontally stacked components 28.

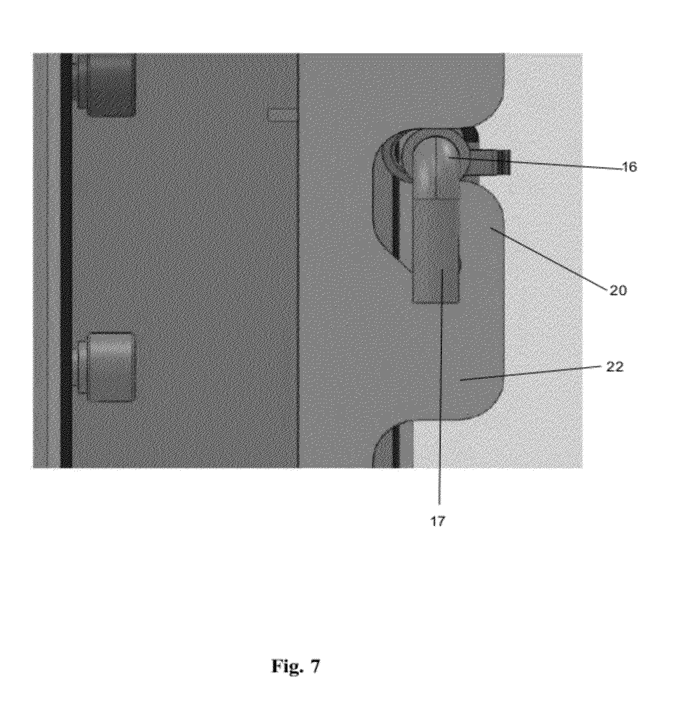

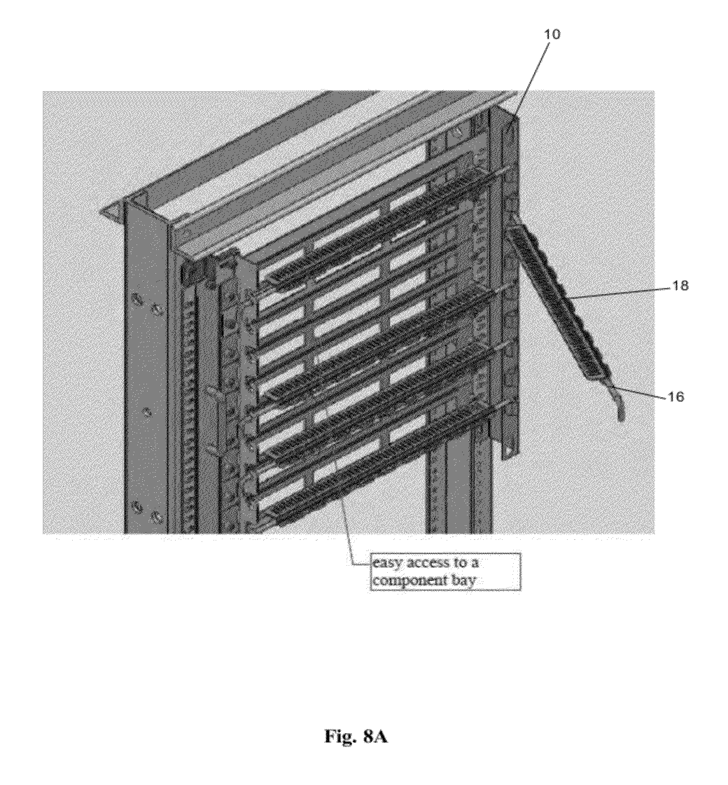

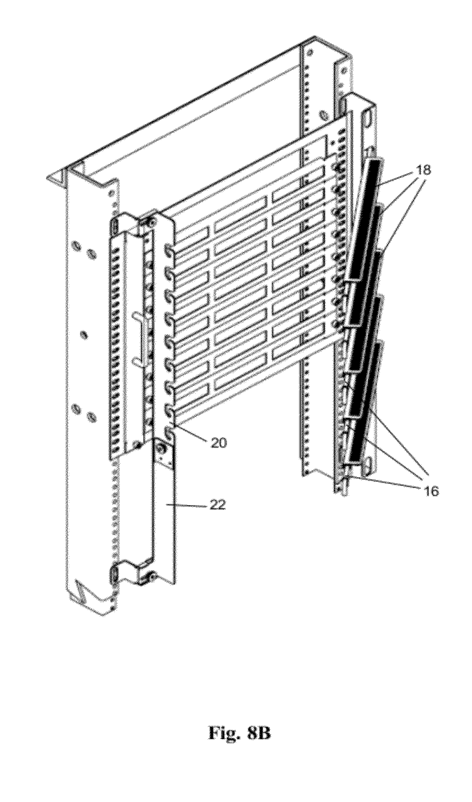

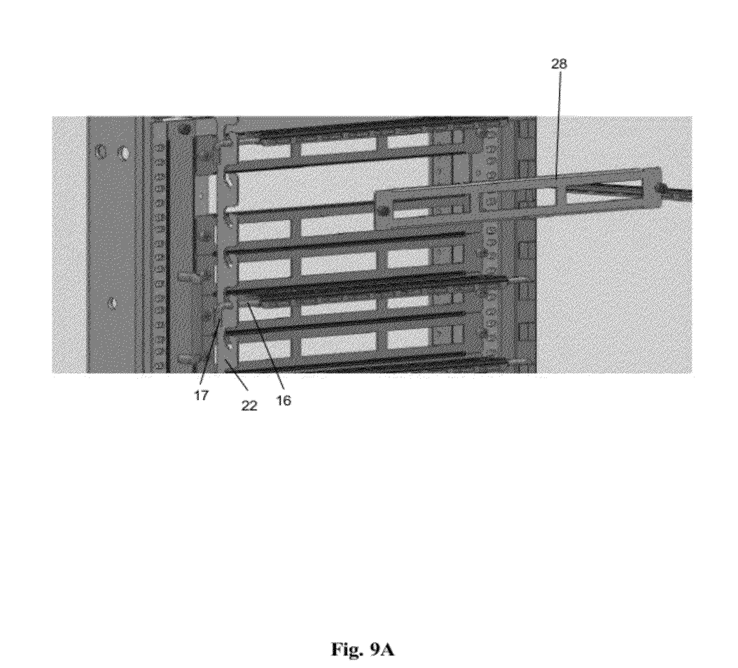

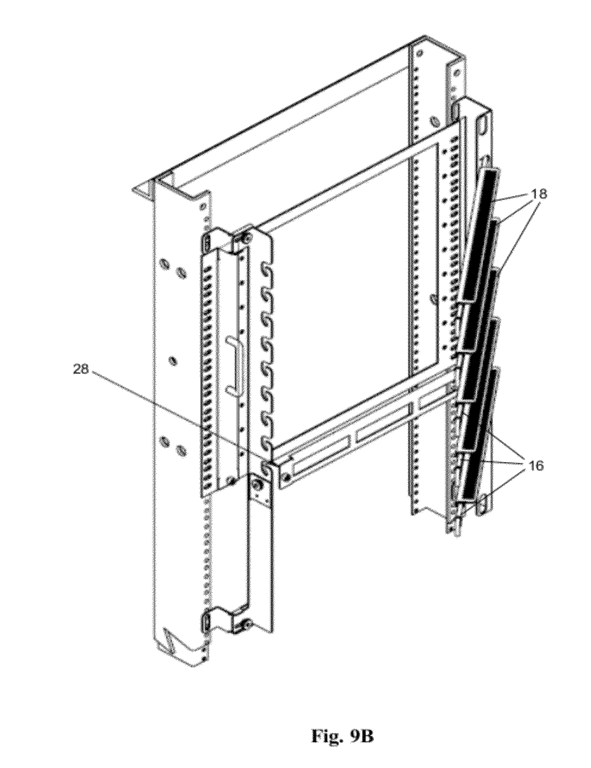

FIG. 7 shows a side elevation view of the free end 17 of the swing arm 16 being moved upwardly in its notch so that it may clear upwardly and out to the right from the hook 20 of the latch plate 22. In FIG. 8A, it can be seen how the entire swing arm 16, with cable support 18 thereon can swing out to the right to permit free access to a component bay for repair or replacement of a component 28, as shown in FIG. 9A. It can be understood that when the swing arm 16 is swung out, the cable(s) for that corresponding component also swings out in an orderly fashion. In FIG. 8B, it can be seen how all swing arms 16 in a released position allowing access to all components 28. FIG. 9B shows the system 10 in an operational state with all but one component 28 removed from the rack 11.

In view of the foregoing, a new and novel system is provided that can enable easy access to fan tray(s) and component(s) of network devices installed in racks.

While the invention has been particularly shown and described with reference to specific embodiments (some of which are preferred embodiments), it should be understood by those having skill in the art that various changes in form and detail may be made therein without departing from the spirit and scope of the present invention as disclosed herein.

What is claimed is:

1. A system for cable management in a network rack, comprising:
a base attached to the rack;
a latch plate attached to the rack system opposite the base; and
at least one swing-arm hingedly attached to the base, the swing-arm having a free end secured to the latch plate.

2. The system of claim 1, further comprising a cable support disposed on the swing arm for attachment of one or more cables.

3. The system of claim 1, wherein the latch plate is configured to release the free end of the swing arm when the latch plate is moved.
